(19) United States
(12) Patent Application Publication
(10) Pub. No.: US 2026/0326615 A1
(43) Pub. Date: Oct. 22, 2026

(54) BATTERY STATE ESTIMATION DURING VEHICLE BATTERY CHARGE EVENT

(71) Applicant: FORD GLOBAL TECHNOLOGIES, LLC, Dearborn, MI (US)

(72) Inventors: Donnell Matthew WASHINGTON, Northville, MI (US); Michael David BEENEY, Canton, MI (US); Yonghua LI, Ann Arbor, MI (US); Gabrielle VUYLSTEKE, Ferndale, MI (US)

(21) Appl. No.: 19/185,827

(22) Filed: Apr. 22, 2025

(51) Int. Cl. B60L 58/16; B60L 53/62; B60L 58/12; G01R 31/374; G01R 31/3835; G01R 31/392

(52) U.S. Cl. CPC B60L 58/16; B60L 53/62; B60L 58/12; G01R 31/374; G01R 31/3835; G01R 31/392; B60L 2240/545; B60L 2240/547; B60L 2260/44

(57) ABSTRACT

A vehicle power system includes a traction battery and a charging system that updates the certified state of the battery during consecutive charge events when the battery reaches a voltage or state of charge below the target completion level. The system incorporates a controller that pauses charging at a predefined point to update the battery's certified state before completing the charge. This predefined voltage or state of charge is determined based on minimizing uncertainty in estimating the battery's state of charge from the open circuit voltage.

### TECHNICAL FIELD

The present disclosure relates to charging a vehicle battery while increasing a state of health (SOH) estimation accuracy for the battery.

### BACKGROUND

Electric vehicles rely on a traction battery for supplying electric power to an electric machine for propulsion. Over time, the capacity and SOH of the traction battery may decrease. An on-board vehicle computer may be configured to update the battery SOH.

### SUMMARY

A vehicle includes a traction battery and a charging system that updates the certified state of the battery during consecutive charge events when the battery reaches a consistent voltage or state of charge below the target completion level.

A vehicle power system includes a controller designed to pause the charging process of a traction battery at a predefined voltage or state of charge and update a certified state of the battery before charging is complete. This predefined point is determined by the level of uncertainty in estimating the state of charge based on the battery's open circuit voltage. The uncertainty may depend on factors such as the battery's voltage or temperature at the start of the charging process.

A method involves pausing the charging process of a vehicle battery at a consistent voltage or state of charge during consecutive charging events, updating the certified state of the battery, and then completing the charging process. This point is determined by minimizing the uncertainty in estimating the state of charge from the open circuit voltage.

### BRIEF DESCRIPTION OF THE DRAWINGS

FIG. 1 illustrates an example block topology of an electrified vehicle illustrating drivetrain and energy storage components.

FIG. 2A illustrates an example waveform diagram of a correspondence relationship between open-circuit voltage (OCV) and state of charge (SOC) of a battery cell.

FIG. 2B illustrates an example waveform diagram of SOC uncertainty at different SOCs.

FIG. 2C illustrates an example diagram of SOC versus time for a charge event.

FIG. 3 illustrates an example flow diagram of a process for estimating battery SOH and performing vehicle operations.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a method and system for charging a battery of an electric vehicle (EV). More specifically, the present disclosure proposes a method and system for charging a battery of an EV while increasing a SOH (e.g., state of certified energy) estimation accuracy.

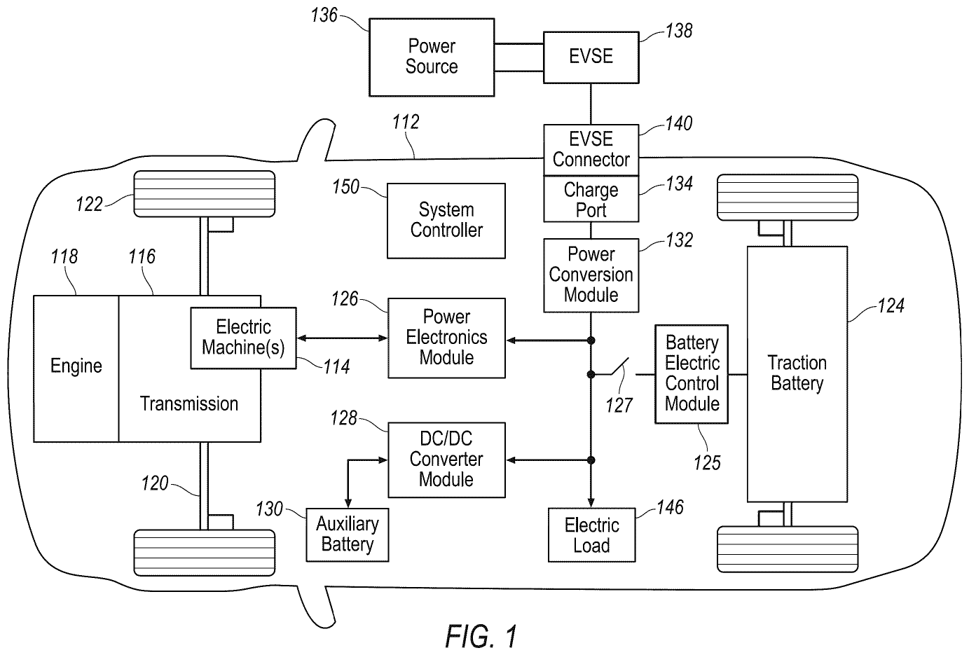

FIG. 1 illustrates a plug-in hybrid-electric vehicle (PH EV). A plug-in hybrid-electric vehicle 112 may comprise one or more electric machines (electric motors) 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to the wheels 122. The electric machines 114 may provide propulsion and slowing capability when the engine 118 is turned on or off. The electric machines 114 may also act as generators and may provide fuel economy benefits by recovering energy that would be lost as heat in the friction braking system. The electric machines 114 may also reduce vehicle emissions by allowing the engine 118 to operate at more efficient speeds and allowing the hybrid-electric vehicle 112 to be operated in electric mode with the engine 118 off under certain conditions.

A traction battery or battery pack 124 stores energy that may be used by the electric machines 114. A vehicle battery pack 124 may provide a high voltage DC output. The traction battery 124 may be electrically coupled to one or more battery energy control modules (BECM) 125. The BECM 125 may be provided with one or more processors and software applications configured to monitor and control various operations of the traction battery 124. The traction battery 124 may be further electrically coupled to one or more power electronics modules 126. The power electronics module 126 may also be referred to as a power inverter. One or more contactors 127 may isolate the traction battery 124 and the BECM 125 from other components when opened and couple the traction battery 124 and the BECM 125 to other components when closed. The power electronics module 126 may also be electrically coupled to the electric machines 114 and provide the ability to bi-directionally transfer energy between the traction battery 124 and the electric machines 114. For example, a traction battery 124 may provide DC voltage while the electric machines 114 may operate using three-phase AC current. The power electronics module 126 may convert the DC voltage to three-phase A C current for use by the electric machines 114. In a regenerative mode, the power electronics module 126 may convert the three-phase A C current from the electric machines 114 acting as generators to DC voltage compatible with the traction battery 124. The description herein is equally applicable to a pure electric vehicle. For a pure electric vehicle, the hybrid transmission 116 may be a gear box connected to the electric machine 114 and the engine 118 may not be present.

In addition to providing energy for propulsion, the traction battery 124 may provide energy for other vehicle electrical systems. The vehicle 112 may include a DC/DC converter module 128 that converts the high voltage DC output of the traction battery 124 to a low voltage DC supply that is compatible with other low-voltage vehicle loads. An output of the DC/DC converter module 128 may be electrically coupled to an auxiliary battery 130 (e.g., 12V battery).

The vehicle 112 may be a battery electric vehicle (BEV) or a plug-in hybrid electric vehicle (PH EV) in which the traction battery 124 may be recharged by an external power source 136. The external power source 136 may be a connection to an electrical outlet. The external power source 136 may be an electrical power distribution network or grid as provided by an electric utility company. The external power source 136 may be electrically coupled to electric vehicle supply equipment (EVSE) 138. The EVSE 138 may provide circuitry and controls to manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EV SE connector 140 may have pins that mate with corresponding recesses of the charge port 134. Alternatively, various components described as being electrically coupled may transfer power using a wireless inductive coupling.

One or more electrical loads 146 may be coupled to the high-voltage bus. The electrical loads 146 may have an associated controller that operates and controls the electrical loads 146 when appropriate. Examples of electrical loads 146 may be a heating module, an air-conditioning module, or the like.

The various components discussed may have one or more associated controllers to control and monitor the operation of the components. The controllers may communicate via a serial bus (e.g., Controller Area Network (CAN)) or via discrete conductors. A system controller 150 may be present to coordinate the operation of the various components. It is noted that the system controller 150 is used as a general term and may include one or more controller devices configured to perform various operations in the present disclosure. For instance, the system controller 150 may be programmed to enable a powertrain control function to operate the powertrain of the vehicle 112. The system controller 150 may be further programmed to enable a telecommunication function with various entities (e.g., a server) via a wireless network (e.g., a cellular network).

The BECM 125 may be configured to perform various operations. For instance, the BECM 125 may be configured to perform the capacity estimation for the traction battery 124 in a periodic manner. The capacity and SOH of the traction battery 124 may reduce over time. After a period of time, the true capacity of the traction battery 124 may be less than the designed capacity when the traction battery 124 is manufactured. An accurate estimation of the true capacity may facilitate the operation and control of the vehicle 112. For instance, an accurate estimation of the true capacity may provide the vehicle user with better range estimation and affect the charging and discharging operations.

The present disclosure proposes a method and system for charging and measuring the SOH of the traction battery 124 based on the characteristics of the battery. More specifically, the present disclosure proposes a method and system for selectively pausing the charging process at one or more strategic SOCs associated with more accurate battery SOC and/or capacity estimations such that accuracy of the SOH estimation of the traction battery 124 may be increased.

It is commonly used in the art to determine the SOC of the traction battery based on an OCV of one or more battery cells as measured. The traction battery 124 may include a plurality of battery cells (not shown) connected in series to achieve the designed battery capacity and voltage. The battery cell OCV may be measured via voltage sensors. The BECM 125 may use the OCV as measured to determine a corresponding SOC of the battery cell via one or more lookup tables (LUTs) and thus determine the overall SOC of the traction battery 124. In general, a higher OCV corresponds to a higher SOC of the battery cell. However, the SOC-OCV curve indicative of a corresponding relationship between the SOC and OCV may not be linear due to the characteristics of the traction battery 124.

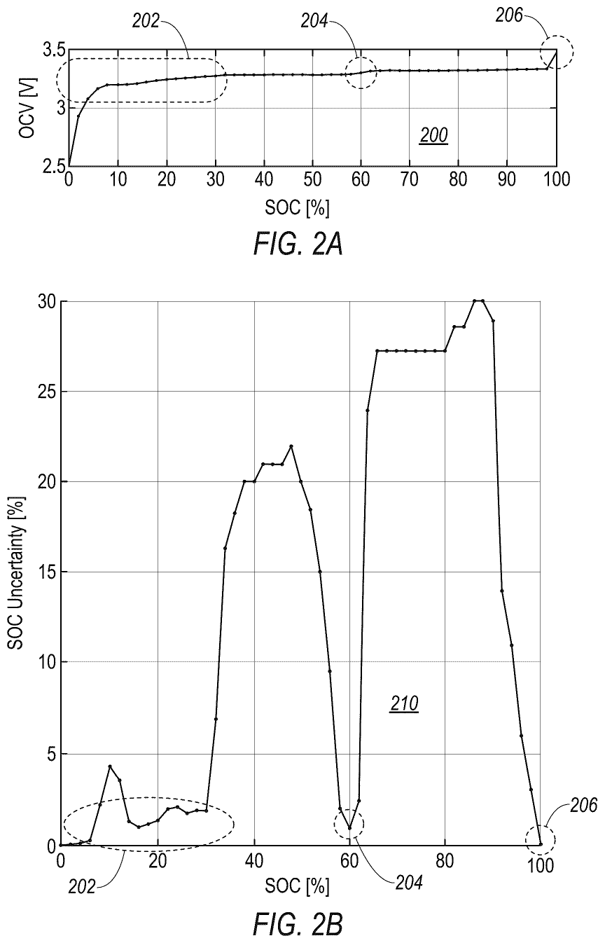

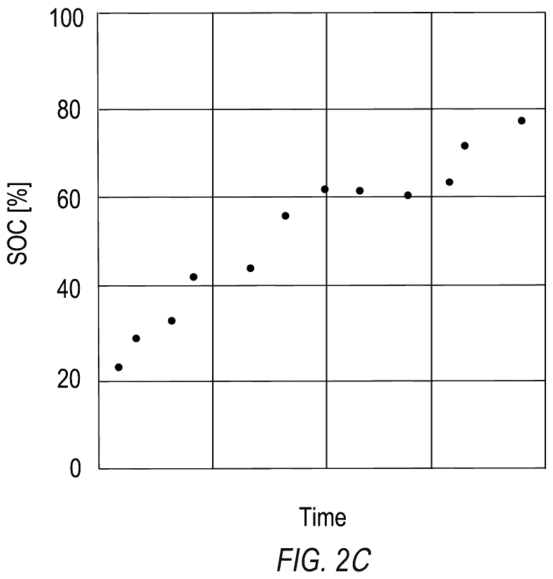

Taking lithium-ion phosphate (LFP) battery cells as an example, the OCV and SOC corresponding relationship is not linear and varies significantly at various SOCs. FIG. 2A illustrates a waveform diagram 200 showing a correspondence relationship between open-circuit voltage (OCV) and state of charge (SOC) of a LFP battery cell of one embodiment of the present disclosure. The horizontal axis x of the waveform diagram 200 denotes the SOC of the battery cell in units of percentage and the vertical axis y of the waveform diagram 200 denotes OCV of the battery cell in units of volts. In the present example, the OCV of the battery cell may increase to approximately 3.5V when fully charged and decrease to approximately 2.5V when depleted. It can be seen from the waveform diagram 200 that the SOC-OCV curve is not linear. More specifically, the SOC-OCV curve may exhibit a steeper slope at three strategic regions, including a first region 202 from 0% to 30% SOC, a second region 204 at around 60% SOC, and a third region 206 from 98% to 100% SOC. The curve outside the three regions is relatively flat. In general, the steeper regions may be associated with less uncertainty in SOC determinations based on OCV and flatter regions may be associated with more uncertainty.

Referring to FIG. 2B, an example waveform diagram 210 of the SOC uncertainty of one embodiment of the present disclosure is illustrated. The horizontal axis x of the waveform diagram 210 denotes SOC of the battery cell in units of percentage and the vertical axis y of the waveform diagram 210 denotes the SOC uncertainty in units of percentage. With continuing reference to FIG. 2A, it can be seen from the waveform diagram 210 that the three strategic regions 202, 204, 206 are associated with significantly lower SOC uncertainties compared with the rest of the uncertainty curve. Therefore, in the present LFP battery cell example, the three strategic regions 202, 204, 206 are preferred for battery state measurements and battery capacity and SOH estimations. As such, during a charge event starting at 40% or 50% SOC for example, the charging may be paused at around 60% SOC so that measurements and certified estimates can be made. The charge event may then continue. Among the three strategic regions 202, 204, 206, the second strategic region 204 and the third strategic region 206 may be more often used than the first strategic region 202 because the battery SOC of 60% and 98-100% more often occur then 0-30%. Additionally, some vehicle users are not comfortable with lower battery SOCs due to so called “range anxiety.” The SOC-OCV uncertainty may be predetermined and stored in the BECM 125 in a non-volatile manner.

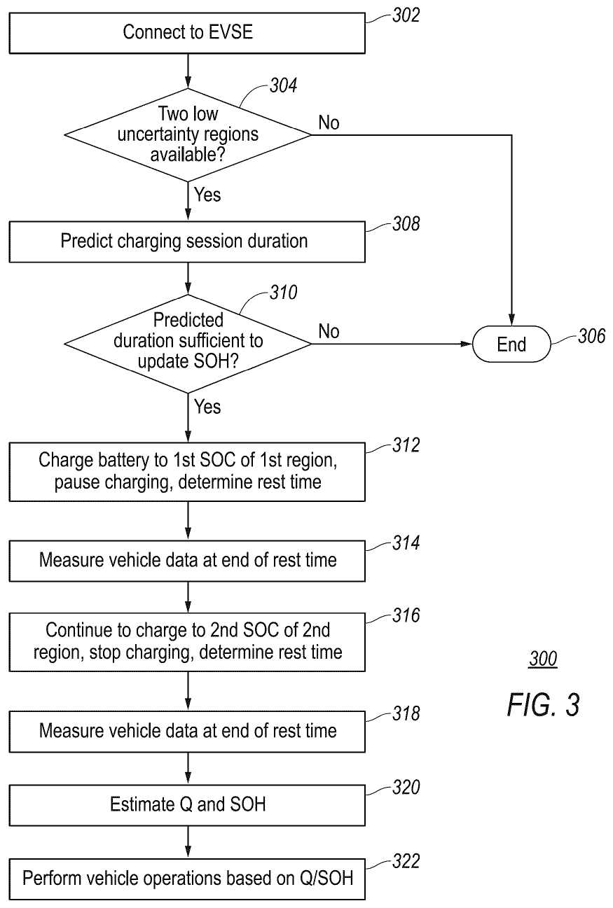

Referring to FIG. 3B, when charging for example from a staring SOC of 20% to a target SOC of 80%, the charge event pauses around 60% while measurements are taken and estimates made as discussed herein. The SOC thus dwells for some period of time around 60%.

As discussed above, the BECM 125 may be configured to perform various operations such as the battery capacity and thus SOH estimations. The SOH of the traction battery 124 may be represented using the equation below:

$$S O H = \frac{{Q}_{True}}{{Q}_{D e s i g n e d}} \times 100 \% \qquad ( 1 )$$

wherein Q_{True} denotes the true capacity as measured/estimated that reflects the presently updated capacity of the traction battery 124, and Q_{Designed} denotes the originally designed capacity of the traction battery. Since the designed capacity Q_{Designed} is known to the BECM 125, the SOH may be determined once the true capacity Q_{True} becomes available. The BECM 125 may be configured to measure vehicle data and estimate the true capacity Q_{True} periodically upon certain conditions being satisfied. For instance, the BECM 125 may be configured to estimate and update the true capacity Q_{True} value using the battery data measured when the SOC uncertainty is low such that the data measurements are relatively accurate.

The battery capacity estimation may be performed based on measurement of voltage and current charged to and/or discharged from the traction battery 124. In an example, the BECM 125 may measure an initial voltage at a first instance and a final voltage at a second instance of the traction battery via one or more voltage sensors. The voltages may be used to estimate SOC of the traction battery 124 at each corresponding instances via the look-up table (LUT) described above. The SOC difference between the first and second instances may be recorded as a ΔSOC. The BECM 125 may further measure the current input/output of the traction battery between the first and second instances and integrate the current as measured to account for the net Amp-hour (Ah) throughput that corresponds to the ΔSOC. Then the total capacity of the traction battery may be estimated based on the ΔSOC and the net Amp-hour throughput. The above capacity estimation is associated with various uncertainties. As discussed above, the LUT may be associated with an inherent SOC uncertainty U(SOC) at each different voltage point especially when the SOC-OCV curve is flat. Additionally, the net amp hour throughput measurement as calculated via the current integration may be also associated with uncertainties.

The uncertainty of the estimated capacity Q_{Est} of the traction battery 124 may be expressed using the following equations:

$$\frac{U ( Q ( k ) )}{Q ( k )} = 100 \% * \sqrt{{( \frac{U ( {\int }_{{CC}_{1}}^{{CC}_{2}} Idt )}{{\int }_{{CC}_{1}}^{{CC}_{2}} Idt} )}^{2} + {( \frac{\sqrt{\begin{matrix}{( U ( {SOC}_{L U T} ( V ( C C 2 ) , T ( C C 2 ) ) ) )}^{2} + \\ {( U ( {SOC}_{L U T} ( V ( C C 1 ) , T ( CC 1 ) ) ) )}^{2}\end{matrix}}}{\begin{matrix}{SOC}_{L U T} ( V ( C C 2 ) , T ( CC 2 ) ) - \\ {SOC}_{LUT} ( V ( CC 1 ) , T ( CC 1 ) )\end{matrix}} )}^{2}} \qquad ( 2 )$$

wherein

$${\int }_{{CC}_{1}}^{{CC}_{2}}$$

Idt denotes the integration of current (e.g., net amp hour throughput) between a first instance when the main contactor 127 is closed and a subsequent second instance when the main contactor 127 is closed. U

$$( {\int }_{{CC}_{1}}^{{CC}_{2}} Idt )$$

denotes the uncertainty associated with the net amp hour throughput measurement as calculated via current integration.

In the present example,

$$U ( {\int }_{{CC}_{1}}^{{CC}_{2}} Idt )$$

is small and can be assumed as approximately equal to zero. In addition,

$$U ( {\int }_{{CC}_{1}}^{{CC}_{2}} Idt )$$

does not vary by different SOCs as illustrated in FIG. 2B. Therefore, the above equation (1) may be simplified as:

$$\frac{U ( Q ( k ) )}{Q ( k )} = 100 \% * ( \frac{\sqrt{\begin{matrix}{( U ( {SOC}_{L U T} ( V ( C C 2 ) , T ( C C 2 ) ) ) )}^{2} + \\ {( U ( {SOC}_{L U T} ( V ( C C 1 ) , T ( CC 1 ) ) ) )}^{2}\end{matrix}}}{{SOC}_{L U T} ( V ( C C 2 ) , T ( C C 2 ) ) - {SOC}_{L U T} ( V ( C C 1 ) , T ( C C 1 ) )} ) \qquad ( 3 )$$

wherein SOC_{LUT}(V(CC1), T(CC1)) denotes the SOC of the traction battery 124 estimated via a SOC-OCV lookup table at the first instance. SOC_{LUT}(V(CC2), T(CC2)) denotes the SOC of the traction battery 124 estimated via the SOC-OCV lookup table at the second instance. The SOC-OCV lookup table may be stored in a non-volatile manner inside a storage of the BECM 125 and/or a storage associated with other components of the vehicle 112. As reflected in the equation, the SOC at time instances may be affected by two major factors: the voltage of the battery cell (e.g., OCV) and the temperature of the battery cell. Both the voltage and the temperature may be measured by one or more battery sensors provided with the traction battery 124.

The SOC-OCV lookup process may be inherently associated with uncertainty. The above equation (3) takes the uncertainty into account by introducing U(SOC_{LUT}(V(CC1),T(CC1))) which reflects the uncertainty associated with the SOC-OCV lookup process at the first instance, and U(SOC_{LUT}(V(CC2),T(CC2))) which reflects the uncertainty associated with the SOC-OCV lookup process at the second instance. Similar to the SOC estimation, the uncertainty associated with the SOC-OCV lookup process is also affected by the voltage (e.g., OCV) and temperature of the battery cells. In the present example, it is assumed that the temperature is constant (e.g., 25° C.) and the uncertainty U only depends on the OCV and thus the SOC of the battery cells. An example SOC-OCV uncertainty lookup table/curve is illustrated in FIG. 2B as discussed previously. The SOC-OCV uncertainty may be stored in a non-volatile manner inside a storage of the BECM 125 and/or a storage associated with other components of the vehicle 112.

The estimated capacity true Q_{True} of the traction battery 124 may be estimated using the following equation:

$${Q}_{True} = \frac{100 \% * {\int }_{{CC}_{1}}^{{CC}_{2}} Idt}{{SOC}_{L U T} ( V ( C C 2 ) , T ( C C 2 ) ) - {SOC}_{L U T} ( V ( C C 1 ) , T ( C C 1 ) )} \qquad ( 4 )$$

Like equation (2),

$${\int }_{{CC}_{1}}^{{CC}_{2}}$$

Idt denotes the integration of current (e.g., net amp hour throughput) between the first instance and the second instance. Here, the time period between the first and second instances may only include the amount of time when the battery 124 is being charged or discharged. The difference in SOC between the first instance and the second instance may be represented as ΔSOC. The uncertainty associated with the SOC difference ΔSOC may be expressed as:

$$U ( Δ SOC ) = \frac{\sqrt{\begin{matrix}{( U ( {SOC}_{L U T} ( V ( C C 2 ) , T ( C C 2 ) ) ) )}^{2} + \\ {( U ( {SOC}_{L U T} ( V ( C C 1 ) , T ( C C 1 ) ) ) )}^{2}\end{matrix}}}{{SOC}_{L U T} ( V ( C C 2 ) , T ( C C 2 ) ) - {SOC}_{L U T} ( V ( C C 1 ) , T ( C C 1 ) )} \qquad ( 5 )$$

From the above equation (5), it may be noted that the uncertainty associated with the SOC difference ΔSOC may vary depending on the SOC-OCV uncertainty associated with the first instance (e.g., CC1) and the subsequent second instance (e.g., CC2). Therefore, the BECM 125 may strategically select two of the three strategic regions 202, 204, 206 as the first instance CC1 and second instance CC2 to minimize the SOC-OCV uncertainties such that the accuracy of the battery capacity estimation may be increased.

Referring to FIG. 3, an example flow diagram of a process 300 for estimating the battery SOH and performing vehicle operations of one embodiment of the present disclosure is illustrated. With continuing reference to FIGS. 1 and 2, the process 300 may be individually or collectively performed by one or more components of the vehicle 112. For instance, the process 300 may be performed by the BECM 125 alone. Alternatively, the process 300 may be performed by the BECM 125 in combination with other components such as the system controller 150 of the vehicle 112. For simplicity, the following description will be made with reference to the BECM 125 although the present disclosure is not limited thereto.

Responsive to detecting the vehicle 112 has been connected to the EVSE 138 to receive electric charge at operation 302, at operation 304, the BECM 125 verifies whether at least two strategic regions associated with the SOC-OCV uncertainty will be available for the present charging session. Continuing with the SOC-OCV uncertainty as illustrated in FIG. 2B, there are three strategic regions 202 (e.g., 0-30%), 204 (e.g., 60%), 206 (98-100%) that are associated with low uncertainties. Depending on the present SOC of the traction battery 124, the charging session may or may not pass through at least two of the strategic regions. For instance, if the present SOC is already at 70% and the battery 124 is expected to be fully charged, then the SOC of the traction battery 124 in the present charging session may pass through the third SOC region 206 at most. The process of the present disclosure may require at least two SOC regions to be available to accurately estimate the true capacity Q_{True} and thus the SOH of the traction battery 124. Therefore, if the answer for operation 304 is no, the process proceeds to operation 306 to end without updating the SOH of the traction battery 124.

Otherwise, if the answer for operation 304 is yes, indicative of at least two SOC regions being available for the present charging session, the process proceeds to operation 308. At operation 308, the BECM 125 predicts a duration of the charging session while the vehicle 112 is continuously connected to the EVSE 138. The BECM 125 may predict the duration of the charging session based on various factors such as a historical charging pattern indicative of how long the vehicle 112 is usually connected to the EVSE 138, a charging location (e.g., home, or outside), type of EVSE 138 (e.g., home EVSE, fast charger), or the like. For instance, if historical data indicates the vehicle 112 is usually connected to the home EVSE 138 overnight for at least 10 hours, the BECM 125 may predict a current charging session at home starting in the evening to be overnight for 10 hours as well. In contrast, if the vehicle 112 is connected to a DC fast charging EVSE 138 located at a service area of a highway, the predicted duration of the charging session may be less than 1 hour.

At operation 310, the BECM 125 determines whether the predicted duration of the charging session is sufficient to update the SOH. In general, a longer charging session is preferred. The BECM 125 may compare the predicted duration with a fixed time threshold (e.g., 8 hours) to perform the determination. Alternatively, a flexible time threshold may be used to determine whether the predicted duration is sufficient. The BECM 125 may determine the flexible time threshold using various factors. For instance, the BECM 125 may determine the flexible time threshold using the initial SOC of the traction battery 124 when the charging session starts. For instance, fully charging the traction battery 124 with an initial SOC of 55% will take significantly shorter time than fully charging the traction battery with an initial SOC of 5%. Thus, the flexible threshold may be negatively correlated with the initial SOC such that a greater initial SOC may result in a shorter flexible time threshold and a lesser initial SOC may result in a longer flexible time threshold. The threshold (either fixed or flexible) may also take the rest time into account. The BECM 125 may pause the charging to allow the battery cells to rest before measuring battery data (to be discussed in detail below).

If the BECM 125 determines the predicted duration of the charging session is below the threshold indicative of it being insufficient to update the SOH of the traction battery 124, the process proceeds from operation 310 to operation 306 to end without updating the SOH.

Otherwise, if the BECM 125 determines the predicted duration of the charging session is above the threshold indicative of it being sufficient to update the SOH of the traction battery 124, the process proceeds to operation 312 and the BECM 125 performs the charging operations to the traction battery 124 until a first instance SOC associated with one of the three strategic regions 202, 204, 206 is reached. Considering the SOC-OCV uncertainty illustrated in FIG. 2B for example, since the SOC-OCV uncertainty is relatively low at the three strategic regions 202, 204, 206, battery data collected within the strategic regions may be more accurate. In this case, the first instance SOC may be within one of the three strategic regions that the battery SOC reaches first. For instance, if the initial SOC of the traction battery 124 is 10%, the first instance SOC may be any value between 10% and 30% SOC within the first strategic region 202. In an alternative example, if the initial SOC of the traction battery 124 is 40%, then the first instance SOC may be 60% associated with the second strategic region 204.

In addition to charging the traction battery, at operation 312, the BECM 125 determines a rest time for pausing the battery charging at the first instance SOC. The reason that a pause/rest is required is that the battery cells may be affected by diffusion immediately after being charged or discharged and the voltage measured immediately after the charging or discharging may not accurately reflect the OCV of the battery cells. In a charging process, the voltage measured across the terminals of the battery cells may be higher than the actual OCV (e.g., up to 15 mV higher in the example illustrated with reference to FIG. 2B), whereas the voltage measured across the terminals of the battery cells in a discharge process may be lower than the actual OCV (e.g., up to 15 mV lower). Therefore, it is preferred to pause the charging process at the first instance SOC for a period of time to allow the battery cells to fully (or sufficiently) rest before the battery data is measured such that battery voltage as measured more accurately reflects the OCV of the battery cells. The time that is sufficient for the battery cells to fully rest may be a fixed time. For instance, a 2-hour rest time may be sufficient for the battery cells to fully rest in most cases. Alternatively, the BECM 125 may further calculate the rest time based on factors including the difference between the initial SOC when the charging session started and the first instance SOC. In general, the rest time and the difference in SOC may be positively correlated. For instance, to reach the first instance SOC of 60%, an initial SOC of 10% requires a greater amount of electric charge and thus a greater degree of diffusion exists compared with charging to 60% from an initial SOC of 55%. The greater degree of diffusion may require a longer rest time to allow the battery cells to fully rest. The rest time as calculated may also be used to determine the time threshold used at operation 310 above.

At operation 314, responsive to detecting the traction battery 124 has rested for the predetermined or calculated period of time, the BECM 125 measures battery data including battery cell voltage, temperature, or the like. Since the battery cells have been fully rested, the battery voltage should accurately reflect the OCV of the cells. The BECM 125 may further determine the SOC of the battery cells and thus the entire traction battery 124 based on the OCV and temperature using the LUT as described above.

At operation 316, once the battery data has been measured, the BECM 125 resumes the charging until the second instance SOC associated with one of the strategic regions 202, 204, 206 has been reached. In the present example, the second instance SOC may be 100% fully charged. Similarly, it is preferred that the battery cells be fully rested at the second instance SOC before the second battery data measurement is performed. The BECM 125 determines the rest time for the second instance SOC in a similar manner as described above with reference to operation 312. Alternatively, a predetermined fixed rest time (e.g., 2 hours) may be used.

At operation 318, responsive to detecting the traction battery 124 has rested for the predetermined or calculated period of time, the BECM 125 measures battery data including battery cell voltage, temperature, or the like and determines the SOC of the battery cells and thus the entire traction battery 124 based on the OCV and temperature at the second instance using the LUT as described above.

At operation 320, the BECM 125 determines the SOC and/or capacity difference between the first instance and second instance and thus the true capacity Q_{True} using equation (4) described above. The BECM 125 further determines the SOH of the traction battery 124 by comparing the true capacity Q_{True} with the designed capacity Q_{Designed} of the traction battery using equation (1) as described above.

With the true capacity Q_{True} and SOH determined, at operation 322, the BECM 125 operates the vehicle 112 and/or the traction battery 124 based on the true capacity Q_{True}. The operations performed by the BECM 125 may include various examples. The BECM 125 may adjust discharging of the traction battery 124 using the true capacity Q_{True} and SOH when the vehicle 112 is driven. For instance, responsive to determining the true capacity Q_{True} and SOH has been reduced since the last estimation, the BECM 125 may provide a shorter-range estimate and reduce the maximum discharge power of the traction battery 124 to conserve electric energy. Alternatively, the BECM 125 may adjust the charging operations based on the true capacity Q_{True} and SOH. As an example, responsive to determining the true capacity Q_{True} and SOH have been reduced, the BECM 125 may reduce the power and/or total amount of battery charging via the EVSE 138 and/or re-generative charging.

The operations of the process 300 may be applied to various situations. As an example, the vehicle 112 is connected to the home EVSE 138 and the charging starts at 30% SOC at 9 PM. The vehicle 112 may be anticipated to have 10 hours charging time based on historical charging records. 2 hours later at 11 PM the traction battery 124 reaches 60% SOC, and the charging pauses for 2 hours to lathe battery cells rest until 1 AM when the battery data is measured and the charging resumes. The 2 hours rest time may be a predefined maximum rest time to allow the battery cells to fully rest since the charging session is anticipated to last 10 hours in the present case. Alternatively, the 2 hours rest time may be determined by the BECM 125 based on the initial SOC of 30% and the first instance SOC of 60%. That is, if the initial SOC of the traction battery 124 is higher, the rest time may be reduced.

Continuing with the above example, the SOC of the traction battery 124 reaches 100% at 5 AM. Similarly, the battery data is not measured immediately after the battery SOC arrives at 100% since the diffusion of the battery cells may still affect accurate measurements. The BECM 125 may wait until the vehicle 112 is disconnected from the EVSE 138 and then performs measurements to the vehicle data when the battery cells are fully rested. For instance, the vehicle 112 is disconnected from the EVSE 138 at 7 AM in the present example. Battery data may be measured by the BECM 125 at 7 AM. The BECM 125 determines and updates the true capacity Q_{True} and SOH based on the data measurements at the first instance (e.g., 60% SOC after rest at 1 AM) and at the second instance (e.g., 100% SOC after rest at 7 AM).

Continuing with the SOC-OCV uncertainty example illustrated with reference to FIG. 2B, the following data calculations demonstrates the advantage of lower uncertainty based on data collected at the second strategic region 204 (e.g., 60% SOC) and the third strategic region 206 (e.g., 100% SOC) in comparison with using data from other regions. As illustrated in FIG. 2B, the SOC uncertainty is approximately 0.9% at 60% SOC and approximately 0.044% at 100% SOC. Applying the above data to equation (5) as discussed above, the SOC uncertainty between 100% and 60% SOC is calculated below:

$$U ( 100 \% - 60 \% ) = \frac{\sqrt{{( 0.044 \% )}^{2} + {( 0.9 \% )}^{2}}}{100 \% - 60 \%} \times 100 \% = 2.25 \%$$

Also illustrated in FIG. 2B, the SOC uncertainty is approximately 20% at 40% SOC for the LFP battery cell. Then the SOC uncertainty between 100% and 40% SOC is calculated below:

$$U ( 100 \% - 40 \% ) = \frac{\sqrt{{( 0.044 \% )}^{2} + {( 20 \% )}^{2}}}{100 \% - 40 \%} \times 100 \% = 33.33 \%$$

The SOC uncertainty between 60% and 40% SOC is calculated below:

$$U ( 60 \% - 40 \% ) = \frac{\sqrt{{( 0.9 \% )}^{2} + {( 20 \% )}^{2}}}{60 \% - 40 \%} \times 100 \% = 100.1 \%$$

As demonstrated by the calculations above, using battery data measured at the strategic SOC regions results in lesser SOC uncertainties and thus more accurate true capacity Q_{True} and SOH estimations.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words controller and controllers may be interchanged herein.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle power system comprising:
a controller programmed to, during charge of a traction battery, pause the charge at a voltage or state of charge of the traction battery and update a certified state of the traction battery before the charge is complete.

2. The vehicle power system of claim 1, wherein the voltage or state of charge is defined by an uncertainty associated with inferring the state of charge from an open circuit voltage.

3. The vehicle power system of claim 2, wherein the voltage or state of charge is associated with lowest values of the uncertainty.

4. The vehicle power system of claim 2, wherein the uncertainty is a function of a voltage of the traction battery at a beginning of the charge.

5. The vehicle power system of claim 2, wherein the uncertainty is a function of a temperature of the traction battery at a beginning of the charge.

6. A method of charging a vehicle battery comprising:
conducting a charge event including the steps of
a) initiating battery charging,
b) pausing the battery charging and updating a certified state of the vehicle battery, and
c) completing the charge event; and
performing the charge event a plurality of times.

7. The method of claim 6, wherein the pausing occurs at a voltage or state of charge that is defined by an uncertainty associated with inferring the state of charge from an open circuit voltage.

8. The method of claim 7, wherein the voltage or state of charge is associated with lowest values of the uncertainty.

9. A vehicle comprising:
a traction battery; and
a charge system configured to, for each of consecutive charge events of the traction battery in which the traction battery achieves a same voltage or state of charge less than a target completion voltage or state of charge, update a certified state of the traction battery responsive to the same voltage or state of charge being achieved.

10. The vehicle of claim 9, wherein the same voltage or state of charge is defined by an uncertainty associated with inferring the state of charge from an open circuit voltage.

11. The vehicle of claim 10, wherein the same voltage or state of charge is associated with lowest values of the uncertainty.

12. The vehicle of claim 10, wherein the uncertainty is a function of a voltage of the traction battery at a beginning of the charge event.

13. The vehicle of claim 10, wherein the uncertainty is a function of a temperature of the traction battery at a beginning of the charge event.
